(19) United States
(12) Patent Application Publication
(10) Pub. No.: US 2025/0323117 A1
(43) Pub. Date: Oct. 16, 2025

(54) DIAMOND STRUCTURES FOR ACTIVE MIXED-SIGNAL PROCESSING AND PASSIVE COOLING IN HETEROGENEOUS CHIPS

(71) Applicant: Advanced Diamond Holdings, LLC, Beltsville, MD (US)

(72) Inventor: John P. Ciraldo, Clarksburg, MD (US)

(21) Appl. No.: 19/176,053

(22) Filed: Apr. 10, 2025

Related U.S. Application Data
(60) Provisional application No. 63/632,372, filed on Apr. 10, 2024.

(51) Int. Cl. H01L 23/373; H01L 23/00; H01L 23/367; H01L 23/538; H01L 23/552; H01L 25/065

(52) U.S. Cl. CPC H01L 23/3732; H01L 23/367; H01L 23/5385; H01L 23/552; H01L 24/16; H01L 25/0657; H01L 2224/16235; H01L 2225/06517; H01L 2225/06541; H01L 2225/06548; H01L 2225/06572; H01L 2225/06589; H01L 2924/35121

(57) ABSTRACT

A vertically stacked 3D integrated circuit structure includes at least two chiplets: a first chiplet formed from a non-diamond semiconductor material, a second chiplet formed from diamond. The diamond chiplet is positioned vertically relative to the first chiplet and is electrically coupled thereto. Thermal vias are formed through one or more of the non-diamond chiplets and include material to form heat extraction pathways. These thermal vias are thermally coupled to a heat-spreading structure, which may include the diamond chiplet, a diamond interposer, or an encapsulating diamond-based packaging layer.

### PRIORITY

This patent application claims priority from provisional U.S. patent application No. 63/632,372, filed Apr. 10, 2024, entitled, “Diamond Chiplets for Active Mixed-Signal Processing and Passive Cooling in Heterogeneous Chips,” and naming John Ciraldo as inventor, the disclosure of which is incorporated herein, in its entirety, by reference.

### FIELD OF THE INVENTION

Illustrative embodiments of the invention generally relate to integrated circuits and, more particularly illustrative embodiments relate to the integration of diamond-based materials for active signal processing and passive thermal management in heterogeneous semiconductor structures.

### BACKGROUND OF THE INVENTION

Thermal management of integrated circuits (ICs) is significant for several reasons, primarily related to the physical properties of the materials involved and the operational reliability and efficiency of the devices. When ICs operate, they consume electrical power, a portion of which is converted into heat due to the resistance in the materials and the switching activities of transistors. This is particularly pronounced in high-performance devices like CPUs, GPUs, and high-speed memory, where billions of transistors switch on and off billions of times per second. Excessive heat can lead to thermal stress on the materials in the IC, potentially causing physical damage or degradation over time. Materials expand when heated and contract when cooled; repeated thermal cycling can cause fatigue in the materials, leading to cracks and other failures. High temperatures can also accelerate electromigration, a process that gradually degrades the pathways in the chip. Many semiconductor materials, including silicon, have properties that vary with temperature.

### SUMMARY

In various embodiments, a three-dimensional (3D) or 2.5D integrated circuit architecture incorporates diamond-based components—such as chiplets, interposers, thermal vias, and packaging layers—to address challenges in thermal management, electromagnetic shielding, and high-frequency signal processing.

In accordance with one embodiment, a vertically stacked 3D integrated circuit structure includes at least three chiplets: a first chiplet formed from a non-diamond semiconductor material (e.g., silicon), a second chiplet formed from diamond, and a third chiplet formed from another non-diamond material. The diamond chiplet is positioned between the other two and is electrically coupled to at least one of them, often serving both active and passive functions. Thermal vias are formed through one or more of the non-diamond chiplets and include material to form heat extraction pathways. These thermal vias are thermally coupled to a heat-spreading structure, which may include the diamond chiplet itself, a diamond interposer beneath the stack, or an encapsulating diamond-based packaging layer.

The diamond chiplet may incorporate circuits for RF, power regulation, or quantum computing, leveraging diamond's wide bandgap, high breakdown voltage, and low dielectric loss.

The vias may be fabricated using low-temperature chemical vapor deposition processes, such as hot filament CVD, at temperatures under 450° C., enabling compatibility with standard IC fabrication protocols. These diamond-filled thermal vias are preferably aligned with high-switching activity zones and may range from 5 to 25 microns in diameter, occupying no more than 10% of the local chiplet cross-sectional area to preserve structural integrity.

Strategic vertical placement of the diamond chiplet further improves thermal performance. In various embodiments, the diamond chiplet is located such that at least a portion of its body resides above 60% of the total stacked height (H) of the integrated circuit. This height-optimized configuration allows the chiplet to intercept rising heat and redistribute it laterally, improving overall thermal efficiency while minimizing the need for multiple heat spreaders.

In some embodiments, the chiplet stack or 2.5D arrangement is built upon or incorporates a diamond interposer. The interposer is configured to provide both electrical routing via embedded copper interconnects and lateral thermal spreading due to its diamond composition. The interposer may be used beneath vertically stacked chiplets or laterally arranged chiplets in a 2.5D configuration. In this arrangement, the thermal vias may extend downward from the chiplets and terminate at the interposer, efficiently removing heat from high-activity zones and redistributing it toward a heat sink or substrate.

In various embodiments, the chiplet stack may be supported on a substrate, such as a silicon, ceramic, or interposer. The substrate can provide structural support, electrical signal routing, or serve as a thermal interface to an external heat sink. However, in some embodiments, no distinct substrate is required. Instead, the chiplets may be vertically stacked and bonded directly to one another using micro-bump interconnects or similar bonding methods. This approach enables a more compact architecture and reduces interfacial thermal resistance between layers. However, various embodiments advantageously include a substrate for integration requirements, such as compatibility with a printed circuit board (PCB), mechanical rigidity, or external connectivity features.

The entire chip structure may be encapsulated in a layered packaging system that includes an inner layer of non-conductive diamond and an outer layer of electrically conductive diamond (e.g., boron-doped diamond). The inner diamond layer passively manages heat by providing an electrically insulating yet highly thermally conductive shell, while the outer conductive diamond functions as a Faraday cage to block electromagnetic interference (EMI) and electromagnetic pulses (EMP). These packaging layers may be thermally coupled to ceramic substrates or external heat sinks to further improve overall system cooling.

In some embodiments, the non-conductive diamond layer is configured to at least partially surround the chiplet stack and, if present, the underlying substrate. This partial encapsulation may include sidewalls and/or a top layer of non-conductive diamond, while leaving the bottom surface exposed for thermal interface material (TIM) attachment or substrate bonding. In other embodiments, the non-conductive diamond may fully encapsulate the chiplet stack and the substrate to form a protective thermal and electrical isolation shell. The degree of encapsulation may vary depending on specific application requirements, such as for environmental sealing, mechanical reinforcement, radiation protection, or selective routing of heat and electrical signals.

The chiplets may be bonded using micro-bump interconnects, and standard packaging geometries and interfaces may be used. This allows the inventive structures to be compatible with existing integration and manufacturing technologies while introducing diamond-based innovations in thermal and electrical performance. The diamond materials, whether in chiplets, interposers, vias, or packaging, are preferably grown using scalable CVD techniques, ensuring manufacturability and cost efficiency.

In accordance with another embodiment, a three-dimensional (3D) or 2.5D integrated circuit structure includes multiple semiconductor chiplets formed from non-diamond materials such as silicon. Between at least two of the chiplets, a diamond interposer is positioned. This diamond interposer includes embedded electrical interconnects that electrically couple the chiplets while also functioning as a high-performance thermal spreader. The interposer may be composed of polycrystalline or single-crystal diamond and provides lateral heat transport toward the outer edges of the integrated circuit. In some versions, the diamond interposer may include a network of through-diamond copper-filled vias, which serve as the electrical interconnects between chiplets.

To further enhance thermal performance, thermal vias containing diamond are formed through one or more of the non-diamond chiplets. These vias are thermally coupled to the diamond interposer and act as vertical conduits for heat removal. The vias are preferably positioned directly beneath regions of high transistor switching density within the chiplets—locations known to generate concentrated heat. The vias may have diameters in the range of 5 to 25 microns and are distributed with a maximum local density of approximately 10% to preserve the mechanical integrity of the surrounding semiconductor. The diamond material may be deposited into the vias using chemical vapor deposition (CVD), preferably a hot filament system operating at temperatures below 450° C. to ensure compatibility with existing chip materials.

In some embodiments, the entire chip stack may be further encapsulated by a dual-layer packaging system. An inner packaging layer of non-conductive diamond provides thermal insulation and high-efficiency heat spreading, while an outer layer of electrically conductive diamond-formed by boron doping-acts as a Faraday cage to protect internal components from electromagnetic interference (EMI) and electromagnetic pulses (EMP). The packaging structure may be thermally coupled to external heat sinks and formed using scalable CVD techniques.

In another embodiment, illustrative embodiments provide a set of chiplets in a planar or 2.5D chip architectures, in which a set of chiplets is arranged side-by-side on a shared substrate. A diamond interposer positioned beneath the chiplets functions both as an electrical routing medium and as a horizontal thermal highway. In these configurations, diamond thermal vias again serve to transport heat from internal chiplet regions downward into the interposer. These planar or semi-planar layouts retain the benefits of diamond-based thermal and electromagnetic enhancements without requiring vertical stacking.

Additionally, methods are provided for manufacturing integrated circuit structures with embedded diamond thermal features. The method includes forming multiple chiplets on a common substrate, positioning a diamond interposer beneath one or more of the chiplets, forming thermal vias through the chiplets, depositing diamond material into the vias using low-temperature CVD processes, and encapsulating the chiplets and interposer with diamond-based packaging layers. The method may further include doping diamond layers to enable electrical conductivity and aligning the thermal vias with simulated or predicted areas of high switching activity to maximize thermal extraction efficiency.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a cross-sectional view of a 3D heterogeneous integrated circuit structure illustrating stacked chiplets in accordance with illustrative embodiments.

FIG. 2 schematically shows a cross-sectional view of a 3D heterogeneous structure in accordance with illustrative embodiments.

FIGS. 3A-3B schematically show cross-sections of thermal vias in a chiplet in accordance with illustrative embodiments.

FIGS. 4A-4B schematically show arrangements for the diamond interposer in accordance with illustrative embodiments

FIGS. 5A-5B schematically shows different configurations of a 2.5D integration in accordance with illustrative embodiments.

FIG. 6 schematically shows a vertical chiplet stack in accordance with illustrative embodiments.

FIG. 7 shows a process of creating thermal vias in accordance with illustrative embodiments.

### DESCRIPTION OF ILLUSTRATIVE EMBODIMENTS

In illustrative embodiments, diamond chiplets are integrated into heterogeneous chips/ICs to serve one or more of the following functions: active mixed-signal processing, passive cooling, and protection from electrical interference. Illustrative embodiments provide diamond chiplets (small-scale semiconductor devices fabricated on diamond), which offer superior thermal conductivity and electrical insulation properties compared to traditional silicon chips. Additionally, a heterogeneous chip architecture incorporates various types of processing units, including digital, analog, and mixed-signal components, to efficiently handle diverse computational tasks. Furthermore, passive cooling structures embedded within the heterogeneous chip dissipate heat generated during operation by leveraging the exceptional thermal conductivity of diamond to enhance heat transfer efficiency. Details of illustrative embodiments are discussed below.

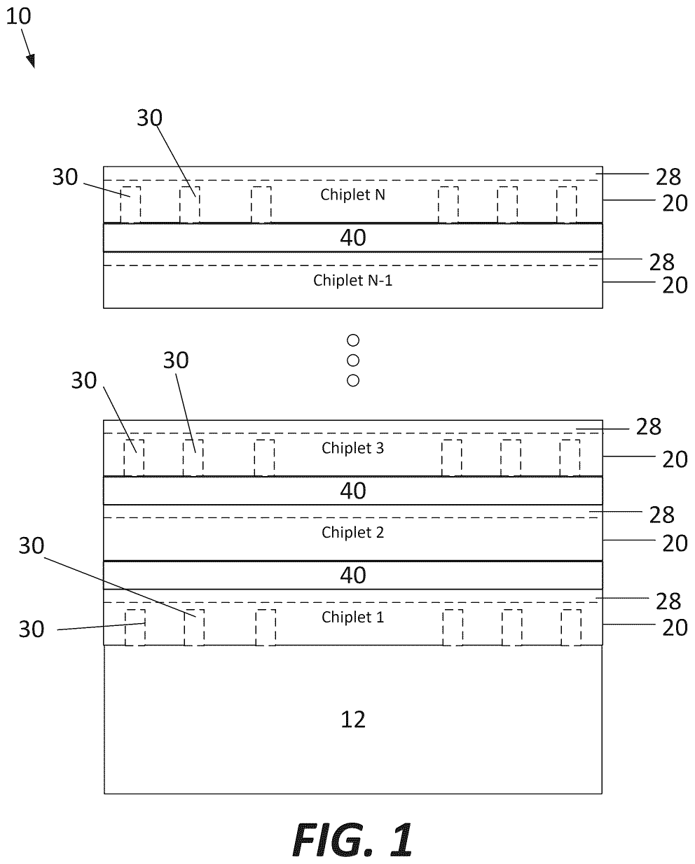

FIG. 1 schematically shows a 3D heterogeneous structure 10 in accordance with illustrative embodiments. A 3D heterogeneous structure 10 refers to a complex architecture where different types of components, materials, or technologies are integrated vertically (in three dimensions) within a single semiconductor device. This approach contrasts with traditional 2D or planar chip designs where components are laid out side by side on a single plane. The term “heterogeneous” emphasizes the integration of dissimilar materials. By stacking chiplets 20 and interconnecting them vertically, data travel distances are reduced, which can significantly improve speed and reduce power consumption. This is particularly important for high-performance computing applications where speed and energy efficiency are critical. It should be understood that various embodiments discussed herein may also be used with a traditional 2D or 2.5D architecture.

Instead of building a single, large monolithic chip, the illustrative embodiments use smaller, modular chiplets 20 that can be developed independently and then connected together to function as a single unit. This modular approach allows for several advantages over traditional monolithic designs. The chiplets 20 can be stacked to form the 3D heterogeneous structure, and can be coupled together, for example by using micro-bump interconnects (e.g., instead of wires). The micro-bump interconnects are used to physically and electrically connect the chiplets in the stack. These tiny solder bumps are placed on the contact pads of each die, and when the dies are aligned and bonded together, the micro-bumps create the physical connections that allow for electrical signals to travel between the chiplets 20.

FIG. 1 shows an example of a heterogeneous structure. The structure includes a substrate 12 (e.g., silicon substrate 12) and a first chiplet 20, such as a digital logic chiplet 20 mounted on the substrate 12. The chiplet 20 may be a digital logic chiplet configured to perform fundamental computational functions. In various embodiments, the first chiplet 20 may be formed from, among other things, silicon. Mounted on the first chiplet 20 is a second chiplet 20. The second chiplet 20 may be, for example, an analog/RF chiplet, which performs functions related to the processing and handling of analog signals and RF communications. The second chiplet 20 may be formed from diamond, such as polycrystalline diamond, although in some embodiments the chiplet 20 may be formed from single-crystal diamond. Stacked on the second chiplet 20 is a third chiplet, which may be, for example, a sensor chiplet 20 formed from a wide band-gap material such as a III-V semiconductor.

Each chiplet 20 includes an active layer 28, which contains the semiconductor devices (e.g., transistors, diodes, capacitors, signal routing circuits, etc.) that perform logic, sensing, signal modulation, or other electrical functions. The active layer 28 is typically located on one surface of the chiplet 20 (e.g., the top side or bottom side depending on orientation), and is a primary source of heat generation within the chiplet 20.

Although three chiplets 20 are illustrated for clarity, some embodiments may include fewer chiplets 20 (e.g., at least one chiplet), while others may include more chiplets 20 (e.g., up to N chiplets 20). It should be understood that the materials and functions described above are merely exemplary, and illustrative embodiments are not limited thereto.

Various embodiments advantageously may include at least one chiplet 20 formed from diamond. Any or all of the chiplets 20 may be formed from diamond. For example, the third chiplet 20 may be formed from diamond (i.e., the chiplet 20 previously described as being formed from the III-V semi-conductor). Advantageously, diamond is a wide bandgap semiconductor that can handle high frequency and high power applications. Thus, diamond serves active electronic applications in the chiplet. Additionally, diamond is also an ideal heat spreader.

Diamond has exceptional thermal conductivity, electrical insulation properties, and mechanical strength, making it an ideal material for heat dissipation and high-performance electronic applications. Leveraging these properties, diamond chiplets 20 provide efficient cooling solutions while enhancing signal processing capabilities.

To that end, in various embodiments, the diamond chiplet 20 spreads heat from other chiplets 20 (e.g., the first and the third chiplets 20) and takes the heat out to the packaging so that thermal hotspots are reduced. A current problem with thermal management is that hotspots in chip structure 10 are very localized. The IC is also packaged, at which point it becomes difficult to measure where the hotspot is formed. The diamond chiplet 20 acts as a heat spreader that moves heat from the hotspot regardless of position of the hotspot. Accordingly, illustrative embodiments insert a diamond chiplet 20 in the 3D heterostructure structure to help with thermal management by acting as a heat spreader from other chiplets 20/hotspots.

In various embodiments, one or more thermal vias 30 may be formed within the material of one or more chiplets 20. These thermal vias 30 extend from the exterior of the chiplet 20 as close as practicable to the active layer 28, enabling efficient extraction of heat generated by the devices formed on the chiplet (e.g., transistors). The thermal vias 30 may contain highly thermally conductive material, such as diamond, and may be used to direct heat away from hotspots and toward heat-spreading structure such as a diamond interposer 40 or thermally conductive packaging. In some embodiments, a diamond interposer 40 may be positioned between two chiplets 20 to provide both electrical interconnection and lateral thermal spreading.

It should be understood that not all chiplets 20 include thermal vias 30, and not all layers require interposers 40 therebetween. For example, one chiplet 20 may be coupled to a heat-spreading interposer 40 and include thermal vias 30, while an adjacent chiplet 20 may be passively cooled or stacked without an interposer 40. As another example, a layer formed from non-diamond material and has a thermal via 30 that leads from the non-diamond material to a diamond chiplet 20 may omit a diamond interposer 40 therebetween. These variations allow for architectural flexibility based on specific performance and thermal management goals. The inclusion or omission of these elements is implementation-dependent and does not limit the scope of the illustrative embodiments.

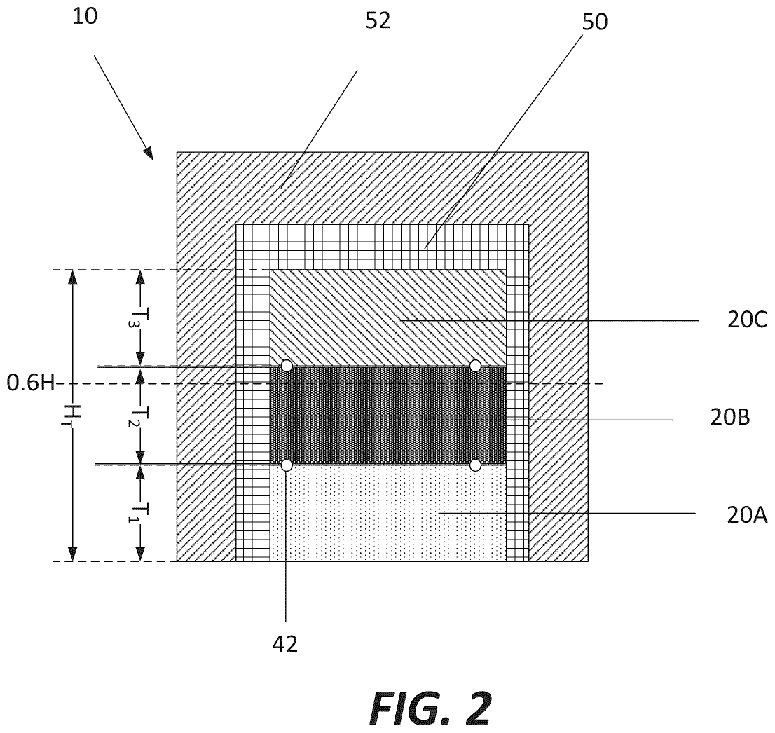

FIG. 2 schematically shows a partial cross-sectional view of a 3D heterogeneous structure in accordance with illustrative embodiments. FIG. 2 is similar to FIG. 1, except that the chiplets 20 are also packaged in diamond (polycrystalline or single crystal diamond). In general, from a manufacturing and cost perspective, it is easier to coat the chiplets 20 in polycrystalline diamond.

Three chiplets 20 are shown for discussion purposes. However, it should be understood that any number of chiplets 20 may be used (e.g., one or more). The first chiplet 20A (e.g., the bottom chiplet), may be formed from silicon. The heterostructure also includes a diamond chiplet 20B, electrically connected to the other chiplets 20 through bumps 42. Above the diamond chiplet 20B is another chiplet 20C, which may also be formed from silicon. Each chiplet 20 performs a function or series of functions, for example, logic, memory, RF signals, quantum processing, etc.

Positioned around the chiplets 20 is a non-conductive diamond 50 (e.g., intrinsic diamond). The non-conductive diamond 50 functions as an electrically insulating layer for the chiplets 20 that provides an electrical barrier. Some embodiments may omit the non-conductive diamond 50 depending on the chip design, e.g., if there are no exposed electrical connections. The non-conductive diamond 50 advantageously operates as a heat spreader. This is particularly advantageous in combination with a diamond chiplet 20B because the diamond chiplet 20B and the non-conductive diamond 50 form a highly-thermally conductive pathway that allows for rapid spreading of heat.

Surrounding the chiplets 20 (and the non-conductive diamond, if present) is an electrically conductive diamond 52. With properly selected dopants (e.g., boron doped diamond) it is possible to make the outer diamond 52 conductive. Both the conductive diamond 52 and/or the non-conductive diamond 50 may be deposited using hot filament reactor, or microwave CVD, for example.

Illustrative embodiments provide a highly conductive polycrystalline diamond. The entire stack may be wrapped in the conductive diamond. This leads to highly advantageous thermal properties. Furthermore, because the 3D heterogeneous structure is wrapped in a conductive package, the conductive diamond 52 can provide a barrier to cross-talk, electrical interference, and EMP. The chip/chiplets 20 therefore become robust to any sort of attack on the chip through electrical pulse, in addition to being highly thermally conductive.

In various embodiments, the conductive diamond 52 layer effectively operates as a Faraday Cage. Electrical fields move around the structure 10 rather than passing through the chip, by creating a counteracting field. Accordingly, the electrically conductive diamond 52 advantageously: (1) passively cools the chip, and (2) protects the chip physically and electrically.

Some embodiments may omit the electrically conductive diamond 52 and just have a non-conductive diamond 50 packaging. Alternatively, in some embodiments, the non-conductive diamond 50 may be omitted and the electrically conductive diamond 52 may be the packaging for the 3D chiplet 20 heterostack 10. Preferably, the non-conductive diamond 50 is positioned between the conductive diamond 52 and the chiplets 20 to prevent electrical coupling between the chiplet 20 and the electrically conductive diamond. However, in some embodiments, the non-conductive diamond 50 may be omitted, and the electrically conductive diamond 52 may contact the chiplets 20 (e.g., when the chiplets 20 do not have exposed electrical connections).

Various embodiments may include all non-diamond chiplets 20. However, some embodiments advantageously may include a diamond chiplet. As an example, there may be a hotspot in the middle of one the non-diamond chiplets 20. The hotspot may be relatively far from the packaging (e.g., non-conductive diamond 50 (if present) and/or the electrically conductive diamond). It is desirable to remove the heat from the hotspot out to the packaging. To that end, some embodiments may have a diamond chiplet 20 in between non-diamond chiplets 20 (e.g., between every pair of non-diamond chiplets 20).

Having multiple diamond chiplets 20 may be undesirable in some circumstances. However, it is desirable to have at least one diamond chiplet 20 in the stack to assist with thermal management. The inventor determined that it is preferable for at least one diamond chiplet 20 to be positioned at a height that is at least partially at or above 60% or 70% the height H_{T} of the chiplet 20 stack (also referred to as at least partially at or above 0.6H or 0.7H). For example, for any arbitrary number of chiplets 20 (n chiplets) having a total stacked height H_{T}, the diamond chiplet 20 is advantageously positioned to have a portion that is at least at 60% of the stacked height H_{T}. It may be even further advantageous to have the diamond chiplet 20 at least at 70% of the stacked height H_{T}. In some embodiments, the entirety of the diamond chiplet 20 is above 0.6H or 0.7H. By positioning the diamond chiplet 20 higher in the stack, it is possible to catch heat from other chiplets 20 as the heat rises. Thus, positioning the diamond chiplet 20 closer to the top of the stack allows for improved heat transfer regardless of the unpredictable positioning of any hotspots, and allows for reduction in the number of diamond chiplets 20. In a similar manner, it is advantageous, particularly when there are no diamond chiplets 20, to have at least one of the interposers 40 at least partially at or above 60% or 70% the height H_{T} of the chiplet 20 stack. In this example, the thickness of the interposer is included the calculation of H_{T}.

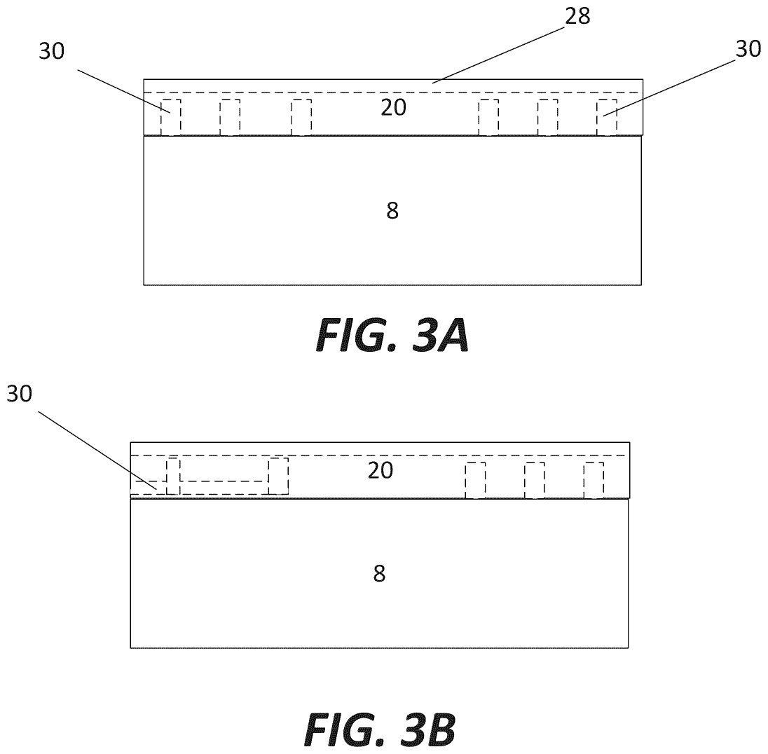

FIGS. 3A-3B schematically show cross-sections of thermal vias 30 in a non-diamond chiplet 20 in accordance with illustrative embodiments. The vias 30 may be formed via laser or etching, and then diamond may be deposited, for example. The chiplet 20 is shown on a heat spreader 8, which can include, among other things, the diamond chiplet 20, the interposer 40, the non-conductive diamond layer 50, the conductive diamond layer 52, and/or the substrate 12. In illustrative embodiments, diamond-containing thermal vias 30 are provided within the chiplet 20 to facilitate highly localized and efficient extraction of heat from internal hotspots. The thermal via 30, in contrast to an electrical via, is a conduit (e.g., vertical conduits in FIG. 3A, bent conduit in FIG. 3B) configured specifically for the transfer of heat rather than electrical signals. In embodiments described herein, these vias are formed by lasering narrow holes into non-diamond chiplets 20—such as silicon chiplets 20—and depositing thermally conductive diamond material therein, preferably polycrystalline diamond deposited via a chemical vapor deposition (CVD) process. Diamond-containing thermal vias 30 are generally not formed in diamond interposers 40 or diamond chiplets 20, as they inherently possess superior thermal conductivity.

The use of diamond in thermal vias 30 is advantageous due to diamond's exceptional thermal conductivity, which significantly outperforms traditional materials such as silicon dioxide or even copper in heat dissipation applications. Furthermore, the vias 30 are able to come very close to the localized heat spot. By directing heat vertically from active transistor junctions or high-switching logic regions to underlying thermal spreaders (e.g., a diamond interposer 40, diamond chiplet, or packaging), these vias serve as thermal tributaries that offload thermal stress from critical functional areas.

Thermal vias 30 are particularly effective in addressing one of the core challenges of 3D IC architectures: the accumulation of heat in vertically stacked layers. In many implementations, the bottom silicon layer of the chiplet 20 stack may be hundreds of microns thick, presenting a significant thermal bottleneck. By integrating diamond-containing vias within these layers, thermal resistance is minimized and thermal flux is dramatically increased—especially when the via exits into a diamond interposer 40 or packaging region that acts as a thermal bus or sink.

Typical dimensions for diamond-containing thermal vias 30 may range from 5 to 25 microns in diameter, with placement targeted toward regions of highest thermal generation (e.g., dense logic or AI processing cores). A maximum aggregate density of diamond vias may be limited to approximately 10% of the local cross-sectional area to preserve the structural integrity of the surrounding chip material and avoid stress from differing coefficients of thermal expansion (CTE).

Fabrication of these vias 30 may involve backside or blind-hole milling followed by CVD diamond deposition. Hot filament CVD systems are particularly advantageous due to their relatively low operating temperatures (e.g., ˜400° C. or lower), which are compatible with modern semiconductor manufacturing processes. Additional enhancements such as localized plasma nucleation, electric or magnetic field guidance, and surface functionalization may be employed to improve the conformal filling of deep or narrow vias and to prevent the formation of voids or vacuum pockets, which can degrade thermal conductivity.

In some embodiments, boron-doped diamond may be used to render the thermal via 30 electrically conductive, enabling dual-function vias that carry both heat and electrical signals when such functionality is desired. However, most thermal vias 30 described herein are intended to remain electrically insulating to maintain isolation between functional layers of the IC.

By enabling direct, targeted heat extraction at or near the nanoscale transistor junctions, diamond-containing thermal vias 30 substantially improve the thermal performance of 2.5D and 3D integrated circuit architectures, reduce the formation of hotspots, and enhance the reliability, performance, and lifespan of advanced computing systems.

While various embodiments describe the integration of diamond interposers 40 and diamond-containing thermal vias 30, it should be understood that these features are not required in all implementations. Depending on the thermal profile, chiplet 20 layout, or manufacturing constraints, either or both of these structure 10 may be omitted in some embodiments without departing from the scope of the disclosed embodiments.

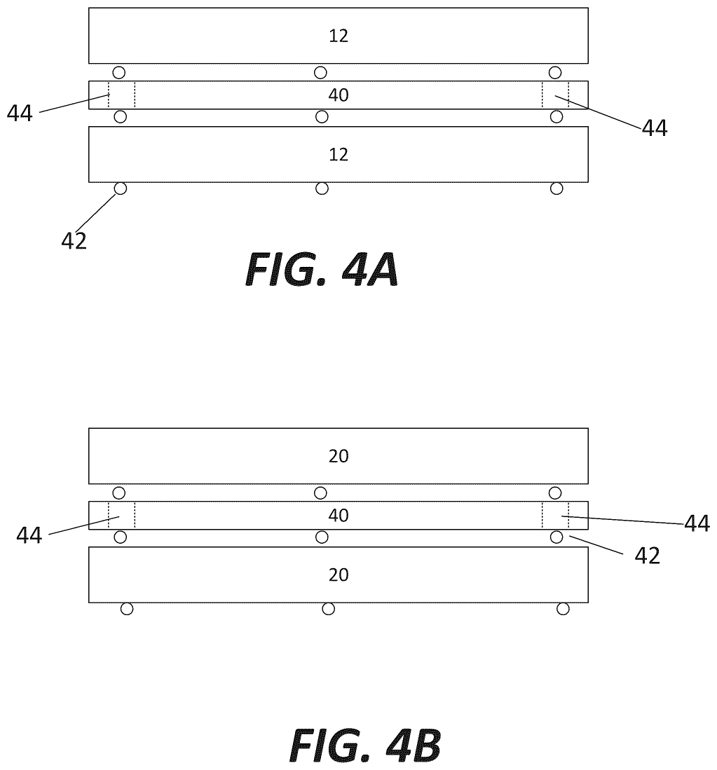

FIGS. 4A-4B schematically show arrangements for the diamond interposer 40 in accordance with illustrative embodiments. In illustrative embodiments, the diamond interposer 40 is provided as a thermally conductive, electrically insulating layer that interfaces between two or more chiplets 20 in a 2.5D or 3D heterogeneous integrated circuit structure. The interposer may be formed from materials such as glass or silicon, which offer limited thermal conductivity and, consequently, limited ability to dissipate localized heat from active devices. In contrast, diamond—particularly polycrystalline diamond—offers exceptionally high thermal conductivity while maintaining electrical insulation when undoped, making it an ideal interposer 40 material for high-density ICs.

In various embodiments, the diamond interposer 40 performs dual roles: (1) it physically and electrically separates stacked or adjacent chiplets 20 while routing electrical signals through embedded electrically conductive vias 44 (e.g., copper-filled vertical interconnects that go all the way through the layer), and (2) it serves as a thermal bus line, extracting heat from chiplets 20 and transporting it laterally toward the package edge or another thermal sink. This dual-functionality enables a substantial improvement in thermal management, especially for high-power devices where localized hotspots could otherwise lead to thermal throttling or premature degradation.

In various embodiments, the diamond interposer 40 may comprise a plurality of through-diamond electrical interconnects formed by copper-filled vias 44. Because diamond is typically an electrical insulator, these copper-filled vias 44 enable the diamond interposer 40 to function not as an electrical routing platform within the integrated circuit structure. This dual-functionality is particularly advantageous in planar or 2.5D architectures, where multiple chiplets 20 are arranged side-by-side and require signal or power interconnections through a shared interposer 40 layer.

The copper-filled vias 44 may be etched holes through the diamond substrate 12 and subsequently filling them with conductive material, such as copper, using standard metallization techniques. Each electrical via 44 provides an isolated electrical pathway between designated contact pads or redistribution layers on opposite sides of the interposer 40. These vertical electrical vias 44 allow the chiplets 20 mounted above the interposer 40 to communicate with one another or with underlying substrate 12 structure 10, such as a package substrate 12 or another interposer 40 layer.

By integrating electrical interconnects 44 into the diamond interposer 40, the structure maintains high electrical connectivity while benefiting from the exceptional thermal conductivity and mechanical stability of diamond. This reduces the need for external wiring or additional routing layers and helps maintain compact, thermally efficient package geometries. Moreover, because the interposer 40 spreads heat laterally while the electrical vias 44 conduct electrical signals vertically, this configuration supports dense chiplet 20 integration and high-performance operation without compromising thermal management.

In some embodiments, the copper vias 44 may be arranged in a regular or irregular grid pattern, depending on the functional layout of the chiplets 20. The interconnect density may vary based on the signal and power requirements of the system, and dielectric passivation layers may be used to electrically isolate the vias from surrounding diamond regions if desired.

In some embodiments, the diamond interposer 40 may be positioned between silicon chiplets 20, between a silicon chiplet 20 and a diamond chiplet, or as a foundation layer for multiple side-by-side chiplets 20 in a 2.5D structure. The interposer 40 may include copper micro-bumps 42 and/or through-diamond vias 44 to electrically couple one or more chiplets 20 to each other or to a packaging substrate 12. Micro-bump 42 interconnects are used to electrically couple adjacent chiplets 20 and/or interposers 40. These bumps 42 may land on metal pads that are connected through electrical vias 44 to the underlying device layers, enabling vertical signal transmission. These electrical vias 44 are distinct from thermal vias 30, which are optimized for heat conduction rather than electrical performance. However, in contrast to thermal vias 30, which preferably include diamond material to maximize heat conduction, electrical via 44s are typically filled with a highly electrically conductive metal, such as copper or tungsten to ensure efficient signal or power transmission between layers. In some embodiments, a thermal via 30 may also function as an electrical via 44 if the diamond material is doped with boron to render it electrically conductive, thereby enabling dual thermal and electrical functionality within the same structure.

In various embodiments, the diamond interposer 40 provides electrical interconnection between chiplets 20 by: (1) through-diamond vias 44 containing conductive materials such as copper; (2) surface metallization or redistribution layers formed on the interposer 40 surface; and/or (3) selectively doped regions of the diamond material itself (e.g., boron-doped diamond) that form electrically conductive paths within the interposer 40.

Furthermore, when integrated with diamond thermal vias 30, the interposer 40 serves as a high-capacity thermal highway, collecting heat from local hotspots through vertical channels formed in non-diamond chiplets 20 (such as silicon), and redistributing it horizontally across the interposer 40 toward thermally conductive packaging. It should be noted that the diamond interposer 40 generally does not include thermal vias 30, as it is already formed from highly thermally conductive diamond. Instead, electrical interconnects (e.g., copper-filled vias 44) are provided through the diamond interposer 40 to enable signal routing and power delivery between chiplets 20.

In some embodiments, the diamond interposer 40 may also serve as a support layer for the diamond chiplet 20 or be coated in doped (electrically conductive) diamond to additionally function as part of an electromagnetic shielding system.

Overall, diamond interposers 40 provide a robust thermal and structural interface within the IC stack 10 and are particularly valuable in systems where passive cooling is desirably closely integrated with logic, memory, RF, or mixed-signal functionality.

However, in various embodiments, the diamond interposer 40 may be omitted entirely. For example, thermal coupling between stacked chiplets 20 and the packaging layer may be achieved through other diamond structure 10, such as diamond chiplets 20 and/or diamond-containing thermal vias 30, without the a dedicated interposer 40.

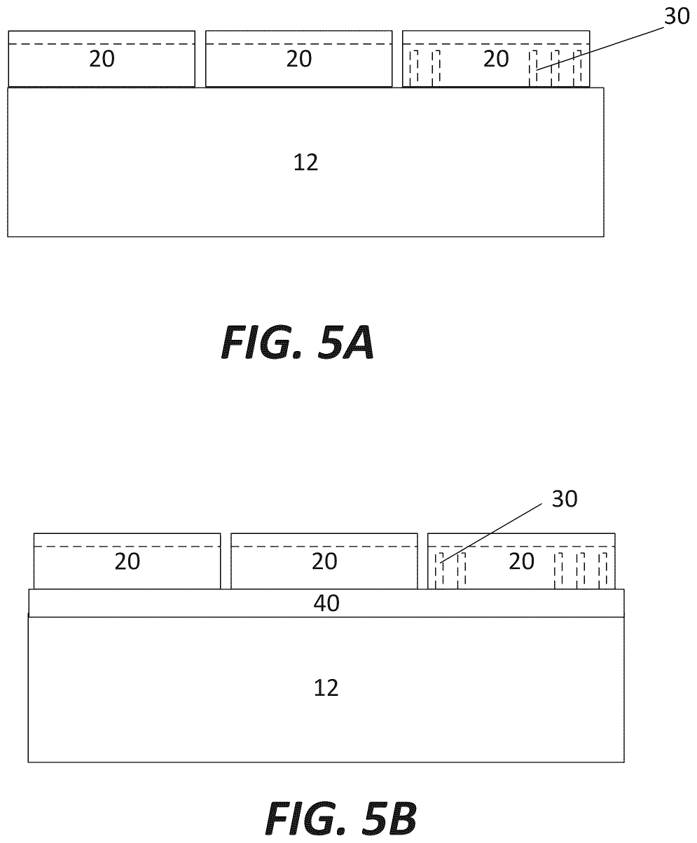

FIGS. 5A-5B schematically shows different configurations of a 2.5D integration in accordance with illustrative embodiments. Although primarily discussed for 3D heterogeneous integration, the diamond-based thermal management structure 10 disclosed herein are also well-suited for use in 2.5D semiconductor architectures (e.g., shown in FIGS. 5A-5B). In a 2.5D system, the chiplets 20 are typically arranged side-by-side on a common interposer 40 (FIG. 5b) or substrate 12 (FIG. 5A), rather than vertically stacked. In such configurations, diamond interposers 40 can replace glass or silicon interposers 40 to provide both electrical interconnection and horizontal heat spreading. This approach is particularly advantageous in high-power applications.

For planar monolithic chips (i.e., traditional 2D ICs), diamond structure 10 such as backside heat spreaders, encapsulating packaging, or thermal vias 30 can still be incorporated to manage thermal loads. For instance, a diamond film deposited beneath a high-power chip can serve as an efficient backside heat extraction layer, especially when coupled to a metallic heat sink or phase change material. Even in the absence of vertical stacking, the modular nature of diamond-based components allows them to be integrated into a variety of existing chip architectures, enhancing thermal reliability, EMI shielding, and power efficiency without requiring a full transition to 3D stacking.

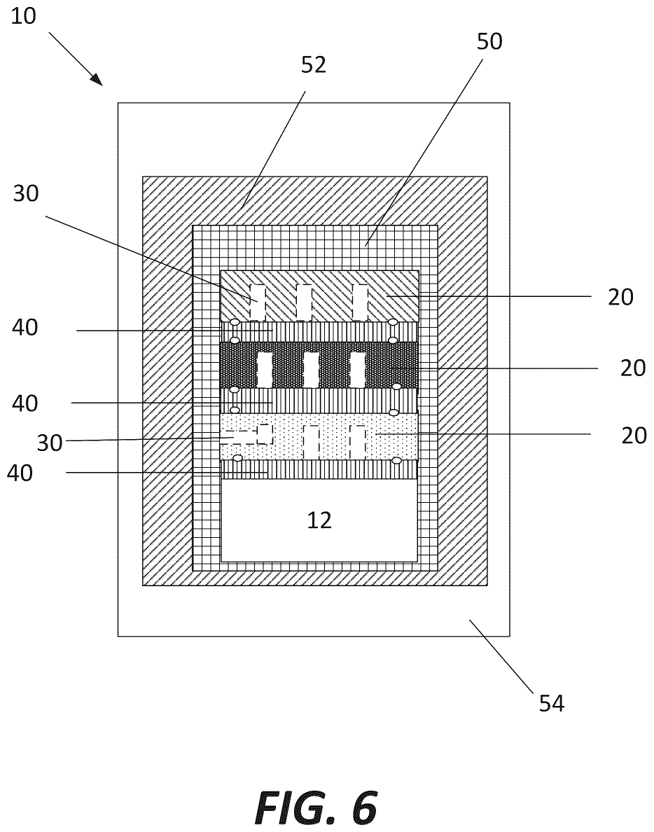

In various embodiments, thermal performance of a 3D integrated circuit stack is enhanced by strategic vertical placement of diamond-based thermal structure 10, such as chiplets 20, interposers 40, or thermal vias 30. As discussed below with reference to FIG. 6, because heat within the chip stack tends to rise, positioning the interposer 40 at or above 60%-70% of the total vertical height of the chip stack (i.e., ≥0.6H or ≥0.7H from the substrate 12) allows the thermal structure to intercept and spread rising heat from lower active layers 28. This height-optimized configuration is particularly effective in designs where only one diamond-based element is used within a multi-layer stack, minimizing material usage while maximizing thermal impact.

Additionally, various embodiments may use the thermal vias 30 alone or in combination with the interposer 40 in various 2.5D configurations. Furthermore, non-conductive diamond 50 and/or electrically conductive diamond 52 may surround and/or encapsulate the 2.5D or planar D2 structure, in a manner similar to the 3D structure described in FIG. 2.

FIG. 6 schematically shows a vertical chiplet 20 stack in accordance with illustrative embodiments. In illustrative embodiments, the integrated circuit (IC) stack 10 is at least partially surrounded by one or more layers of diamond packaging material that serve both thermal and electromagnetic shielding functions. The inner packaging layer may comprise non-conductive diamond 50, such as intrinsic or lightly doped polycrystalline diamond, which acts as a high-efficiency thermal spreader. This layer 50 provides a passive heat dissipation path from chiplets 20, interposers 40, or thermal vias 30 to the outer packaging 54 boundary, enhancing the ability to manage localized hotspots.

Surrounding the non-conductive diamond 50 may be the electrically conductive diamond 52 shell, formed for example by boron doping. In various embodiments, this outer layer 52 functions as a Faraday cage, providing electromagnetic interference (EMI) and electromagnetic pulse (EMP) protection. The conductive diamond 52 absorbs and redistributes incoming electromagnetic fields, preventing them from penetrating into the IC and affecting internal components. This dual-layer packaging—comprising an inner thermal insulator and outer electromagnetic shield—can either fully encapsulate the IC stack or partially surround it, depending on the design. In some embodiments, portions of the packaging may include openings or cutouts to allow for signal I/O, thermal interface materials (TIMs), or direct mounting to a heat sink or board. The packaging geometry may be customized for use in harsh environments such as aerospace, defense, or high-reliability automotive systems.

Some embodiments may provide ceramic packaging 54 outside of the electrically conductive diamond 52 layer. Various embodiments may include openings in the electrically conductive diamond 52 and/or non-conductive diamond 50 to allow for electrical connections. Furthermore, a larger heat sink may be mounted underneath the 3D heterogeneous structure.

It should be understood that various embodiments may employ a number of other diamond components work together to create thermal transport pathways, removing heat from junctions and delivering it to external heat sinks or ambient surroundings. Illustrative embodiments introduce a comprehensive diamond-based thermal management system for heterogeneous integrated circuits. This system may include the use of one or more of:
Diamond chiplets 20 for active signal processing and passive heat spreading.
Diamond interposers 40 to electrically and thermally couple chiplets 20 within a 2.5D or 3D stack.
Diamond-containing thermal vias 30 for localized extraction of heat from hotspots.
Diamond packaging (non-conductive and conductive) to provide a thermally conductive shell and optional electromagnetic shielding (Faraday cage).

These components may work together to create thermal transport pathways, removing heat from junctions and delivering it to external heat sinks or ambient surroundings. The combination of diamond's superior thermal conductivity, electrical insulating properties (or conductivity if doped), and mechanical robustness makes it uniquely suited for these roles.

By combining the diamond-containing thermal vias 30 that channel heat from localized hotspots at lower layers upward to the strategically placed diamond chiplet 20 or interposer 40 or outer diamond layers 50, 52. In various embodiments, the diamond structure at the upper levels serves as a thermal hub, collecting heat delivered by the vias 30 and redistributing it laterally toward the packaging. This therefore reduces the number of diamond elements used in various embodiments while maintaining effective thermal coverage, and may also improve mechanical balance and stress distribution throughout the chip structure.

The diamond chiplets 20 are small, modular semiconductor units fabricated using polycrystalline or single-crystal diamond. These chiplets 20 can perform active functions, such as high-frequency analog or RF processing, or quantum computing operations. They also act as passive thermal spreaders due to their ultra-high thermal conductivity. Diamond chiplets 20 are preferably placed at or above 60% of the total height of a 3D chip stack (i.e., ≥0.6H) to optimally intercept rising heat.

Various embodiments of the invention provide a comprehensive thermal and functional solution for next-generation integrated circuits, particularly within high-density 2.5D and 3D heterogeneous architectures. The system-level integration of diamond chiplets 20, diamond interposers 40, diamond-containing thermal vias 30, and diamond-based packaging structure 10 offers a wide range of performance and reliability benefits.
Enhanced Signal and Mixed-Signal Processing: Diamond chiplets 20 can support high-speed analog, RF, and even quantum processing functions, benefiting from diamond's ultra-wide bandgap, high breakdown voltage, and exceptional electrical isolation. These active chiplets 20 reduce signal degradation and improve performance in mixed-signal and high-frequency environments, such as 6G transceivers or QPUs (quantum processing units).
Advanced Thermal Management: Passive cooling elements such as diamond interposers 40 and strategically placed diamond chiplets 20 extract heat from stacked or planar chiplets 20. Diamond-containing thermal vias 30 provide vertical thermal transport directly from transistor-level hotspots, routing heat into thermal bus lines (chiplets 20 or interposers 40), and ultimately out through packaging. This enables precise, localized thermal control and alleviates thermal stress across the IC.
Compact and Modular Design: Illustrative embodiments eliminate the need for bulky external heat sinks by embedding cooling functionality directly within the IC. Modular integration of passive and active diamond-based components allows designers to tailor thermal pathways to the specific layout and heat distribution of each device, whether in 2.5D side-by-side configurations or vertically stacked 3D structure 10.
Energy Efficiency and System Longevity: By maintaining lower and more uniform chip temperatures, these embodiments reduce or eliminate the need for active cooling systems (e.g., fans, thermoelectric devices), thereby lowering overall system power consumption. Reduced thermal cycling and hotspots also improve long-term reliability and reduce failure rates from electromigration, material fatigue, or delamination.
EMI/EMP Protection: Packaging the chip stack in boron-doped, electrically conductive diamond 52 enables the formation of an effective Faraday cage. This mitigates the effects of electromagnetic interference (EMI) and electromagnetic pulses (EMP), making these solutions particularly valuable for rugged, mission-critical applications.

The inventor believes that these embodiments are valuable across a range of high-performance and harsh-environment computing applications, including:
High-Performance and AI Computing: Diamond-enhanced ICs can address the growing thermal and electrical demands of AI/ML accelerators, GPUs, and scientific simulation hardware, supporting both compute density and sustained performance without throttling.
Edge Computing and Embedded Systems: The compact, passively cooled architecture is ideal for edge environments where size, power, and ambient cooling are constrained. Thermal vias 30 and diamond interposers 40 allow fine-grained thermal routing even in non-stacked (2.5D) configurations.
Aerospace, Defense, and Automotive: The physical durability, radiation hardness, and thermal resilience of diamond-based systems make them ideal for deployment in extreme environments-such as high-altitude aircraft, space-based platforms, military electronics, or electric vehicle power systems.

The various components (e.g., thermal via 30, interposer 40, diamond chiplet 20, packaging 52) may be thermally coupled, such that a thermal connection between two components enables the transfer of heat from one component to the other with minimal thermal resistance. Thermal coupling may occur through direct physical contact, such as where diamond material of a thermal via 30 physically abuts the surface of a heat-spreading structure—e.g., a diamond chiplet 20, diamond interposer 40, or a packaging layer. For instance, the diamond material of the via 30 may protrude from the via 30 or terminate flush with the surface of the thermally conductive structure, such that heat is directly conducted from the via 30 into the adjacent diamond element.

Alternatively, thermal coupling may occur through the presence of an intermediary thermally conductive material between the via 30 and the heat-spreading structure. Examples of such intermediary materials include copper, silver, indium, and metallic micro-bump structures commonly used in microelectronic assemblies. These materials exhibit high thermal conductivity and enable effective thermal transfer even if the diamond material is not in direct contact with the final heat sink or thermal bus layer.

In some embodiments, thermal coupling may be achieved even in the presence of intervening interface layers, adhesives, bonding agents, or metallization layers, so long as the overall assembly provides an efficient thermal conduction pathway to the heat-spreading component. In this context, thermally coupled encompasses both monolithic and modular structures that are physically connected, mechanically bonded, or laminated in such a manner that heat flow is substantially continuous between the source and the heat sink or dissipative layer.

Accordingly, thermally coupled should be interpreted to include both direct and indirect thermal pathways, provided that the thermal conductivity of the interface is sufficient to extract heat from a device region and deliver it to a structure capable of spreading or dissipating the heat. This does not include incidental or non-functional thermal contact—for example, configurations where the thermal resistance is so high that meaningful heat transfer cannot occur. In the context of illustrative embodiments, thermal coupling implies a thermally efficient interface that materially contributes to heat removal from an active device region or hotspot and delivers that heat to a spreading or dissipative structure, such as a diamond interposer, chiplet, or packaging layer.

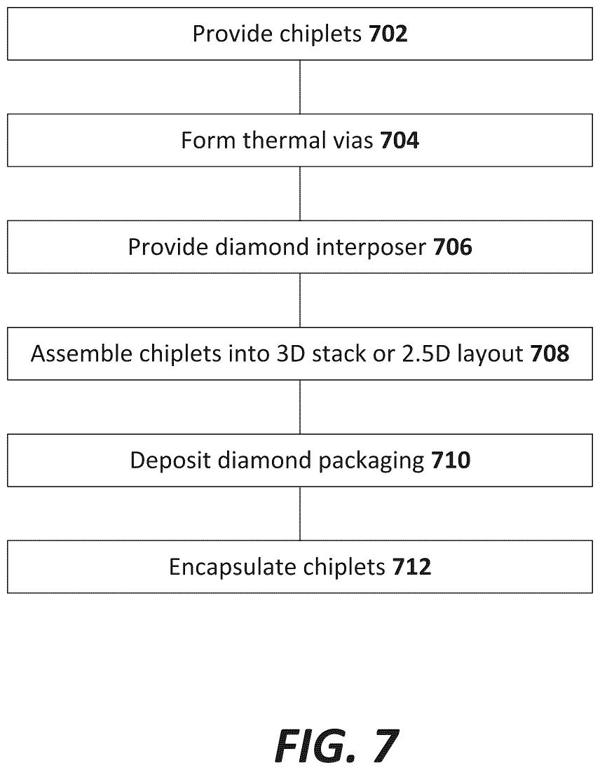

FIG. 7 schematically shows a process 700 of manufacturing an integrated circuit in accordance with illustrative embodiments. It should be noted that this method is substantially simplified from a longer process that may normally be used. Accordingly, the method shown in FIG. 7 may have many other steps that those skilled in the art likely would use. In addition, some of the steps may be performed in a different order than that shown, or at the same time. Furthermore, some of these steps may be optional in some embodiments. Accordingly, the process 700 is merely exemplary of one process in accordance with illustrative embodiments of the invention. Those skilled in the art therefore can modify the process as appropriate.

The process begins at step 702, which provides the chiplets 20 that are incorporated into the integrated circuit (IC) stack. The process may receive ready-made chiplets 20 or chiplets 20 manufactured using appropriate semiconductor materials tailored to their specific functions. For example, chiplets 20 performing logic, memory, or sensing tasks may be fabricated from silicon, silicon carbide (SiC), gallium nitride (GaN), or other III-V semiconductors. In contrast, chiplets 20 intended for high-power processing or thermal management may be fabricated using diamond, either in polycrystalline or single-crystal form. Each chiplet 20 includes the active layer 28 that contains the functional circuitry—such as transistor and diodes—and serves as a primary source of heat during operation.

In various embodiments, one or more of the chiplets 20 may be diamond chiplets 20 provided to perform both active and passive functions. The diamond chiplets 20 are fabricated using polycrystalline or single-crystal diamond and may be configured to support high-power, high-frequency, or quantum computing functions. Due to diamond's ultra-wide bandgap and high breakdown voltage, diamond chiplets 20 are particularly well-suited for handling RF signal processing, power regulation, and 6G/mmWave transceiver operations. In quantum applications, diamond chiplets 20 may host defect centers (e.g., NV centers) and serve as quantum processing units (QPUs). Regardless of their specific function, the diamond chiplets 20 simultaneously serve as thermal spreaders, passively removing heat from adjacent components through the chiplet 20 body itself.

The integration of diamond chiplets 20 provides an advantage by consolidating functional electronics and thermal management within the same physical module. For example, in a 3D heterogeneous IC stack, a diamond chiplet 20 may be positioned between two silicon chiplets 20—serving both as an active RF module and as a thermal buffer between heat-generating layers. This dual-purpose enables more compact chip designs, reduces reliance on external cooling components, and allows for thermal load balancing across the IC stack. In some embodiments, a diamond chiplet 20 may include embedded logic, analog circuitry, or wide-bandgap transistors fabricated directly on or into the diamond substrate 12, further expanding its functional versatility. However, various embodiments may not include any diamond chiplets 20.

At step 704, the process forms thermal vias 30 into the chiplets 20. In non-diamond chiplets 20, such as those formed from silicon, thermal vias 30 may be formed to extract heat from localized hotspots. This process typically involves laser cutting or etching vertical via 30 holes from the backside or within the chiplet 20 material, extending the vias 30 as close as practical to the active layer 28. Diamond material—preferably polycrystalline diamond—is then positioned in the via holes using chemical vapor deposition (CVD) techniques, such as hot filament CVD (HFCVD) or microwave plasma CVD. In some embodiments, boron doping may be applied during deposition to produce dual-function vias that offer both thermal conductivity and electrical signal transmission.

For diamond-containing thermal vias 30, the deposition process becomes more complex due to the aspect ratio of the via holes and the desire for conformal filling. Shallow vias 30 (e.g., 5-25 μm diameter, <100 μm depth) can be filled more uniformly, but deeper structure 10 may exhibit non-uniform deposition, resulting in voids or air pockets, which significantly reduce thermal conductivity. To address these challenges, various enhancement strategies may be employed. These include:
Localized plasma nucleation control, such as shaping the filament or electrode geometry to focus plasma into via trenches;
Application of magnetic or electric fields to direct reactive ions deeper into the vias;
Use of nucleation seeding agents or surface functionalization to promote bottom-up diamond growth;
Adjusting gas composition and pressure to improve step coverage and reduce shadowing effects.

One major constraint in integrating diamond with conventional IC materials is the coefficient of thermal expansion (CTE) mismatch between diamond and silicon or metal interconnect layers. Diamond's extremely low CTE (˜1 ppm/° C.) can lead to mechanical stress and potential delamination when integrated with higher-CTE materials that expand and contract more during thermal cycling. To mitigate these effects, the density and size of diamond inclusions—e.g., keeping diamond vias 30 to less than 10% of the local cross-sectional area—or implement stress-relief layers or graded transition zones between diamond and adjacent materials. Additionally, careful thermal cycling protocols and layer-by-layer deposition can help reduce abrupt thermal gradients during processing.

Temperature sensitivity of the underlying IC components is another fabrication concern. Many modern chips cannot tolerate sustained exposure to temperatures exceeding 400° C. without degradation. Therefore, HFCVD is preferred over microwave plasma CVD, which typically requires higher temperatures (˜700-800° C.).

In certain embodiments, the thermal vias 30 described herein may be formed from electrically conductive diamond, achieved through boron doping of the diamond material during chemical vapor deposition. These dual-function vias offer both thermal and electrical conductivity, enabling new routing strategies within densely integrated 3D or 2.5D chip structure 10. Electrically conductive diamond 52 vias may be used to carry power or signal lines in addition to dissipating heat, thereby reducing the need for separate electrical interconnects and enhancing integration density.

The use of conductive diamond 52 provides several unique advantages over traditional metal vias. Diamond offers high breakdown voltage, radiation hardness, and exceptional current-carrying capacity, making it ideal for high-voltage, high-temperature, or radiation-exposed environments such as aerospace or defense systems. Additionally, the combination of electrical and thermal transport through a single via structure simplifies routing and can reduce parasitic inductance and resistance in power distribution networks.

At step 706, the diamond interposer 40 is provided. When a diamond interposer 40 is used, the process may form a thin polycrystalline diamond sheet via CVD, followed by the creation of through-diamond electrical vias 44. These vias are etched through the diamond layer and filled with conductive materials such as copper to enable signal and power routing. Surface metallization, redistribution layers, or micro-bump 42 structure 10 may be added to support chiplet 20 attachment and electrical interconnectivity across the interposer 40 surface.

At step 708, the chiplets 20 and the interposers 40 (if any) are assembled into either a vertically stacked (3D) structure or a laterally arranged (2.5D planar) layout. Each chiplet 20 is aligned and bonded using micro-bump 42 interconnects, which serve as the physical and electrical coupling mechanisms between chiplets 20. The diamond interposer 40 may be placed between chiplets 20 to facilitate both electrical routing and lateral thermal spreading.

In illustrative embodiments, the diamond-based thermal management structure 10 described herein—such as chiplets 20, interposers 40, vias 30, and packaging—are designed to be fully compatible with conventional semiconductor materials and integration methods. For example, diamond chiplets 20 may be mounted atop or between standard silicon, silicon carbide (SiC), gallium nitride (GaN), or III-V semiconductor chiplets 20, using established micro-bump 42 interconnect technology. Diamond interposers 40 can replace or supplement traditional glass or silicon interposers 40, leveraging the same electrical via 44 architectures while offering superior thermal performance. Similarly, diamond-containing thermal vias 30 may be embedded within standard silicon chiplets 20 without altering the electrical architecture, allowing for targeted cooling without disrupting existing circuit designs.

This hybrid approach enables seamless adoption of diamond materials within existing fabrication and packaging ecosystems. For instance, a conventional logic chiplet 20 stack may be enhanced with a strategically placed diamond chiplet 20 or interposer 40 to manage thermal loads, while still maintaining standard power delivery networks, I/O interfaces, and substrate 12 bonding methods. In some embodiments, traditional ceramic or metallic heat sinks may be thermally coupled to the diamond packaging to further extend heat dissipation into the environment. These integration pathways ensure that the benefits of diamond-based thermal solutions can be incrementally adopted into current system-on-chip (SoC), multi-chip module (MCM), or 2.5D/3D IC designs without requiring major process changes, thus supporting rapid commercialization and scalability across a range of high-performance electronics applications.

As mentioned previously, diamond structure 10—such as chiplets 20, thermal vias 30, interposers 40, and packaging layers—are fabricated using chemical vapor deposition (CVD) techniques. Among the available methods, hot filament CVD (HFCVD) is particularly advantageous due to its ability to operate at relatively low temperatures (approximately 350-450° C.), which are compatible with semiconductor-grade silicon and other IC materials. HFCVD involves passing a hydrocarbon gas (e.g., methane) mixed with hydrogen over heated filaments, creating a reactive plasma that promotes diamond nucleation and growth on the substrate 12 surface. This technique supports deposition on large-area wafers and is especially suited for growing polycrystalline diamond films, which offer high thermal conductivity suitable for heat-spreading and packaging applications.

Following assembly, at step 710, diamond packaging layers may be deposited to enhance thermal and electromagnetic performance. First, a non-conductive diamond 50 layer (intrinsic or lightly doped) is deposited around or over the chiplet 20 stack using CVD to act as a thermal spreader and electrical insulator. Next, an outer layer of electrically conductive diamond, such as boron-doped diamond, may be added to form a Faraday cage, thereby shielding the internal components from electromagnetic interference (EMI) and electromagnetic pulses (EMP).

At step 712, the packaging and integration steps are performed. These may include the application of a ceramic or metallic housing, such as a black ceramic case, as well as the addition of thermal interface materials (TIMs), external heat sinks, or board-level interconnects. The chiplet 20 assembly is then connected to system-level substrate, printed circuit boards (PCBs), or ceramic carriers using standard packaging interfaces. The integrated circuit stack 10 may be encapsulated with additional housing materials, such as black ceramic or metallic enclosures, which offer both mechanical protection and supplemental heat spreading. The process then comes to an end.

As used in this specification and the claims, the singular forms “a,” “an,” and “the” refer to plural referents unless the context clearly dictates otherwise. For example, reference to “the integrated circuit” in the singular includes a plurality of integrated circuits, and reference to “the via” in the singular includes one or more vias and equivalents known to those skilled in the art. Thus, in various embodiments, any reference to the singular includes a plurality, and any reference to more than one component can include the singular.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein.

It is, therefore, to be understood that the foregoing embodiments are presented by way of example only and that, within the scope of the appended claims and equivalents thereto, inventive embodiments may be practiced otherwise than as specifically described and claimed. Illustrative embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure. Disclosed embodiments, or portions thereof, may be combined in ways not listed above and/or not explicitly claimed. Thus, one or more features from variously disclosed examples and embodiments may be combined in various ways. For example, it is to be understood that the present disclosure contemplates that, to the extent possible, one or more features of any embodiment can be combined with one or more features of any other embodiment.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A three-dimensional (3D) integrated circuit structure comprising:
a first chiplet formed of a non-diamond semiconductor material;
a second chiplet formed of diamond, wherein the second chiplet is vertically positioned with respect to the first chiplet and electrically coupled thereto;
at least one thermal via extending through the first chiplet, the thermal via comprising diamond material positioned within the via, the diamond material being thermally coupled to a heat-spreading structure;
wherein the heat-spreading structure comprises either the second chiplet, a diamond interposer, and/or a diamond-based packaging layer.

2. The structure of claim 1, wherein the second chiplet comprises a radio frequency (RF), power management, or quantum processing circuit formed on or within the diamond material.

3. The structure of claim 1, wherein the diamond chiplet is positioned such that at least a portion of the diamond chiplet is positioned at least in part above 60% of a total stacked height (H) of the integrated circuit structure.

4. The structure of claim 1, wherein the integrated circuit structure is at least partially surrounded by a non-conductive diamond layer and an outer electrically conductive diamond layer.

5. The structure of claim 4, wherein the electrically conductive diamond layer is boron-doped and configured to function as a Faraday cage.

6. The structure of claim 1, wherein the diamond thermal via has a diameter between 5 and 25 microns.

7. The structure of claim 1, wherein the thermally conductive structure is thermally coupled to an external heat sink or ceramic substrate.

8. The structure of claim 1, wherein the diamond thermal via is formed using hot filament chemical vapor deposition at a temperature less than 450° C.

9. The structure of claim 1, further comprising a third chiplet formed of a non-diamond semiconductor material, the third chiplet being vertically stacked with respect to the second chiplet, wherein the chiplets are physically coupled using micro-bump interconnects.

10. The structure of claim 1, wherein the thermal via includes diamond material to conduct heat from a localized region within the chiplet to a thermally conductive structure.

11. A three-dimensional (3D) or 2.5D integrated circuit structure comprising:
a plurality of chiplets formed of non-diamond semiconductor materials;
a diamond interposer positioned between at least two of the chiplets, the diamond interposer comprising electrical interconnects to electrically couple the chiplets, and being formed at least in part from polycrystalline or single-crystal diamond;
one or more thermal vias extending through at least one of the chiplets, the thermal vias having diamond material therein and being thermally coupled to the diamond interposer, wherein the diamond interposer functions as a thermal spreader.

12. The structure of claim 11, wherein the diamond interposer laterally transports heat from the thermal vias to an outer edge of the integrated circuit structure.

13. The structure of claim 11, wherein the thermal vias have a diameter between 5 and 25 microns and occupy no more than 10% of a cross-sectional area of the chiplet.

14. The structure of claim 11, wherein the thermal vias are filled using hot filament chemical vapor deposition.

15. The structure of claim 11, wherein the integrated circuit structure is configured in a 2.5D layout, and the chiplets are arranged laterally over the diamond interposer.

16. The structure of claim 11, further comprising a packaging structure comprising:
an inner layer of non-conductive diamond at least partially surrounding the chiplets and interposer, and
an outer layer of electrically conductive diamond configured to function as a Faraday cage.

17. An integrated circuit package comprising:
one or more semiconductor chiplets;
a thermal packaging structure at least partially surrounding the chiplets, the thermal packaging structure comprising:
a first layer formed from non-conductive diamond to provide thermal insulation and heat spreading; and
a second layer formed from electrically conductive diamond configured to shield the chiplets from electromagnetic interference (EMI) and electromagnetic pulses (EMP).

18. The package of claim 17, wherein the electrically conductive diamond is boron-doped.

19. The package of claim 17, wherein the packaging structure is thermally coupled to an external heat sink.

20. The package of claim 17, wherein the non-conductive diamond and conductive diamond layers are deposited using chemical vapor deposition.
